(19) United States
(12) Patent Application Publication
(10) Pub. No.: US 2009/0325369 A1
(43) Pub. Date: Dec. 31, 2009

(54) Semiconductor device and method of fabricating the same

(75) Inventors: Yong-Soo Kim, Icheon-si (KR); Moon-Sig Joo, Icheon-si (KR); Heung-Jae Cho, Icheon-si (KR); Won-Joon Choi, Icheon-si (KR)

Correspondence Address: LOWE HAUPTMAN HAM & BERNER, LLP, 1700 DIAGONAL ROAD, SUITE 300, ALEXANDRIA, VA, 22314, US

(73) Assignee: Hynix Semiconductor Inc., Icheon-si (KR)

(21) Appl. No.: 12/318,469

(22) Filed: Dec. 30, 2008

(30) Foreign Application Priority Data
Jun. 30, 2008 (KR) 10-2008-0063183
Oct. 8, 2008 (KR) 10-2008-0098625

(51) Int. Cl. H01L 21/3205

(52) U.S. Cl. 438/585; 257/E21.158; 257/E21.24; 257/E21.294

(57) ABSTRACT

A method of fabricating a semiconductor device includes forming a gate dielectric on a substrate, forming a gate structure on the gate dielectric, the gate structure comprising a stacked layer of a silicon layer and a metal layer, selectively etching the gate structure to form a gate pattern, forming a capping layer surrounding the gate pattern, plasma-treating the capping layer, and performing a gate reoxidation process

### CROSS-REFERENCES TO RELATED APPLICATIONS

The present application claims priority of Korean patent application numbers 10-2008-0063183 and 10-2008-0098625, filed on Jun. 30, 2008, and Oct. 8, 2008, respectively, which are incorporated herein by reference in their entirety.

### BACKGROUND

The present disclosure relates to the technology of fabricating semiconductor devices, and in particular, to a semiconductor device which includes a gate electrode having a polymetal structure, and a method of fabricating the same. More particularly, the present disclosure relates to a method of fabricating a semiconductor device, including, in one or more embodiments, performing a gate reoxidation process while suppressing the interfacial oxidation of polymetal, without being affected by metal contamination, and the semiconductor device thereby formed.

Recently, in order to provide operation characteristics required in high-integrated semiconductor devices, semiconductor devices use gate electrodes having a so-called polymetal structure in which high-melting-point and low-resistance metal layers such as a polysilicon (Poly-Si) layer and a tungsten (W) layer are sequentially stacked. The gate electrode having the polymetal structure, has a Poly-Si/WN/W structure in which a polysilicon (Poly-Si) layer, a tungsten nitride (WN) layer and a tungsten (W) layer are sequentially stacked. The tungsten nitride layer serves as a diffusion barrier for preventing a reaction between the tungsten layer and the polysilicon layer during fabrication processes.

Micro-trench and plasma damage occur on a gate dielectric when forming a gate pattern by selectively etching a gate structure in which a polysilicon layer, a tungsten nitride layer and a tungsten layer are sequentially stacked on the gate dielectric. A gate reoxidation process is performed for curing the damage of the gate dielectric. Since the tungsten layer rapidly expands in volume while being oxidized in a gate reoxidation process, a selective oxidation process is used which oxidizes only the polysilicon layer, not the tungsten layer or the tungsten nitride layer. See, Selective Oxidation of Silicon (100) vs. Tungsten Surfaces by Steam in Hydrogen, Journal of the Electrochemical Society, Volume 150, Issue 10, pp. G597-G601 (October 2003).

FIGS. 1A and 1B are cross-sectional views depicting stages in a typical method of fabricating a flash memory device including a gate electrode having a polymetal structure.

Referring to FIG. 1A, a gate dielectric 12, also called a tunnel insulating layer, is formed on a substrate 11, and a gate structure is formed on the gate dielectric 12. The gate structure includes a first polysilicon layer 13 serving as an electric charge storing layer, a dielectric layer 14, a second polysilicon layer 15, a tungsten nitride layer 16 serving as a diffusion barrier layer, a tungsten layer 17, and a gate hard mask layer 18. The foregoing layers are sequentially stacked on the gate dielectric 12.

A photoresist pattern (not shown) is formed on the gate hard mask layer 18, and the gate structure is etched by using the photoresist pattern as an etch barrier to thereby form a gate pattern 19. During this process, micro-trench and plasma damage occur on the surface of the gate dielectric 12 and the lower edge of the gate pattern 19 which are exposed when forming the gate pattern 19. This damage is depicted in FIG. 1A as wavy lines on the upper surface of the gate dielectric 12. Moreover, plasma damage also occurs on both sides of the exposed dielectric layer 14.

In order to recover the gate dielectric 12 and the dielectric layer 14 from the micro-trench and the plasma damage, the gate reoxidation process is performed by using the selective oxidation process as illustrated in FIG. 1B. It can be seen that the gate dielectric 12 under the lower edge of the gate pattern 19 has become thicker through the gate reoxidation process, and oxide layers 13A and 15A are formed only on the sides of the first and second polysilicon layers 13 and 15 without oxidizing the tungsten layer 17 and the tungsten nitride layer 16.

As described above, when the gate electrode having the polymetal structure is used, the characteristics of the device are enhanced through the gate reoxidation process. However, the gate reoxidation process introduces several problems that will now be described with reference to FIGS. 2, 3A and 3B.

FIG. 2 is a graph of retention characteristic curves according to metal contamination in a typical flash memory device including a gate electrode having a polymetal structure.

Specifically, FIG. 2 is a graph of retention characteristic curves at thermal treatment times T1 and T2 (T1<T2) at temperature(s) higher than 300° C. It can be seen from FIG. 2 that the retention characteristic deteriorates as thermal treatment time increases. This is because an electric charge stored in the first polysilicon layer 13 serving as the electric charge storing layer leaks out due to metal contamination caused by a metal-based byproduct produced during the gate reoxidation process.

Specifically, the typical gate reoxidation process is performed at a high temperature of, for example, approximately 700° C. to approximately 900° C. using H₂O gas or O₂ gas. Thus, the tungsten layer 17 reacts with the H₂O gas or the O₂ gas to produce a gaseous metal-based byproduct such as the WH₂O₄ or WOₓ. The produced metal-based byproduct contaminates the substrate 11 and a chamber, deteriorating the electrical properties of a semiconductor device in subsequent processes, especially thermal treatment.

Furthermore, even when the metal-based byproduct produced in the gate reoxidation process is completely removed through a subsequent cleaning process, if the thermal treatment is performed in an oxygen atmosphere like a subsequent process of forming a gate spacer oxide layer, metal contamination is caused because the same metal-based byproduct as in the gate reoxidation process is produced.

The above-described metal contamination also occurs in an electrode having a polymetal structure which uses metals other than W, such as Mo, Ta, Ti, Ru, Ir and Pt.

FIGS. 3A and 3B illustrate the polymetal interface of a typical semiconductor device including a gate electrode having a polymetal structure. Specifically, FIG. 3A is a picture of the cross section of the polymetal interface, and FIG. 3B is a graph with curves illustrating the analysis result of the component of the polymetal interface, which is analyzed using Electron Energy Loss Spectroy (EELS).

Referring to FIGS. 3A and 3B, it can be seen that a SiOₓ dielectric layer having a thickness greater than 2 nm is formed on interfaces where the tungsten nitride layer 16 contacts the tungsten layer 17 and the second polysilicon layer 15 after the gate reoxidation process. The dielectric layer increases the vertical resistance of the gate, causing problems such as signal delay during high frequency operation.

### SUMMARY

One or more embodiments are directed to a semiconductor device including a gate electrode having a polymetal structure that prevents metal contamination in a gate reoxidation process, and a method of fabricating the same.

One or more embodiments are directed to a semiconductor device including a gate electrode having a polymetal structure that is capable of improving the vertical resistance of a gate electrode by suppressing or preventing oxidation of an interface where a metal layer contacts a polysilicon layer in a gate reoxidation process, and a method of fabricating the same.

One or more embodiments are directed to a semiconductor device including a gate electrode having a polymetal structure that is capable of preventing oxidation of a metal layer in a gate reoxidation process, and a method of fabricating the same.

One or more embodiments are directed to a method of fabricating a semiconductor device, the method including: forming a gate dielectric on a substrate; forming a gate structure on the gate dielectric, the gate structure including a stacked layer of a silicon layer and a metal layer; selectively etching the gate structure to form a gate pattern; forming a capping layer surrounding the gate pattern; plasma-treating the capping layer; and performing a gate reoxidation process.

In one or more embodiments, plasma-treating the capping layer may be performed by using oxygen (O₂) plasma. The plasma-treating the capping layer includes: forming plasma in a chamber by using an inert gas; and flowing oxygen gas (O₂) into the chamber where the plasma is formed.

In one or more embodiments, plasma-treating the capping layer may be performed at a temperature lower than that of the gate reoxidation process. The plasma-treating the capping layer may be performed at a temperature of approximately 50° C. to approximately 250° C. The gate reoxidation process may be performed at a temperature of approximately 700° C. to approximately 900° C.

The gate reoxidation process may be performed by using a mixed gas of an oxygen-containing gas and a hydrogen-containing gas. The oxygen-containing gas may include an H₂O gas or an O₂ gas, and the hydrogen-containing gas may include an H₂ gas.

The capping layer may be formed at a temperature of approximately 50° C. to approximately 250° C. The capping layer may include a silicon oxide layer. The capping layer may be formed by an atomic layer deposition (ALD) process or a plasma enhanced atomic layer deposition (PEALD) process.

In one or more embodiments, forming the capping layer includes: loading the substrate, on which the gate pattern is formed, into a chamber; flowing a silicon source gas into the chamber; purging the silicon source gas; flowing an oxygen source gas into the chamber; and purging the oxygen source gas. The flowing the silicon source gas and flowing the oxygen source gas may include flowing gas containing an amine group into the chamber together with the silicon source gas and the oxygen source gas. The capping layer may be formed in a plasma atmosphere. The plasma atmosphere may be formed by using an argon gas or a nitrogen gas.

In one or more embodiments, the gate structure may include a stacked layer including a silicon layer, a metal layer, and a gate hard mask layer which are sequentially stacked, or a stacked layer including a charge storage layer, a dielectric layer, a silicon layer, a metal layer, and a gate hard mask layer which are sequentially stacked. The charge storage layer may include a silicon layer or a dielectric layer.

In accordance with one or more embodiments, a method of fabricating a semiconductor device includes: forming a gate dielectric on a substrate; forming a gate structure on the gate dielectric, the gate structure including a stacked layer of a silicon layer and a metal layer; selectively etching the gate structure to form a gate pattern; forming a capping layer surrounding the gate pattern; plasma-treating the capping layer; and performing a gate reoxidation process in a plasma atmosphere.

In one or more embodiments, performing the gate reoxidation process includes: forming plasma in a chamber by using an inert gas; and flowing a mixed gas of an oxygen-containing gas and a hydrogen-containing gas into the chamber where the plasma is formed. The oxygen-containing gas may include an H₂O gas or an O₂ gas, and the hydrogen-containing gas may include an H₂ gas. The gate reoxidation process may be performed at a temperature of approximately 200° C. to approximately 900° C.

### BRIEF DESCRIPTION OF THE DRAWINGS

FIGS. 1A and 1B are cross-sectional views depicting stages in a method of fabricating a typical flash memory device including a gate electrode having a polymetal structure.

FIG. 2 is a graph of retention characteristic curves according to metal contamination in a typical flash memory device including a gate electrode having a polymetal structure.

FIG. 3A is a picture of a cross section of a polymetal interface.

FIG. 3B is a graph with curves illustrating the analysis result of the component of the polymetal interface, which is analyzed using Electron Energy Loss Spectroy (EELS).

FIGS. 4A to 4D are cross-sectional views depicting stages in a method of fabricating a semiconductor device in accordance with one embodiment.

FIGS. 5A to 5C are cross-sectional views depicting stages in a method of fabricating a semiconductor device in accordance with another embodiment.

FIG. 6 is a time graph of exemplary curves for parallel processes in a process of forming a capping layer by using an atomic layer deposition (ALD) process.

FIG. 7 is a graph of data points on curves illustrating a metal-contamination degree according to presence and absence of the capping layer.

FIGS. 8A and 8B are a picture and a graph illustrating a polymetal interface of the semiconductor device including the gate electrode having the polymetal structure to which the capping layer is applied in accordance with one or more embodiments.

FIGS. 9A and 9B are graphs illustrating measured characteristics of the capping layer in accordance with one or more embodiments.

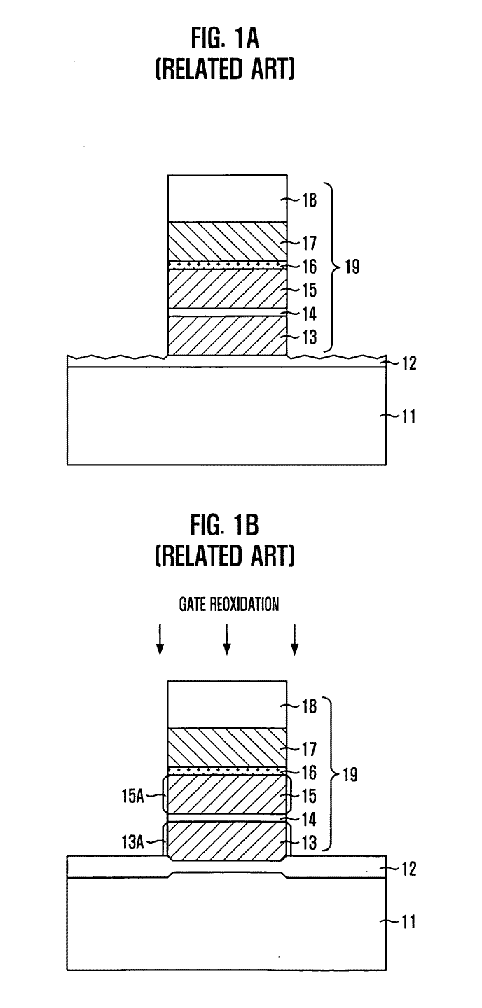

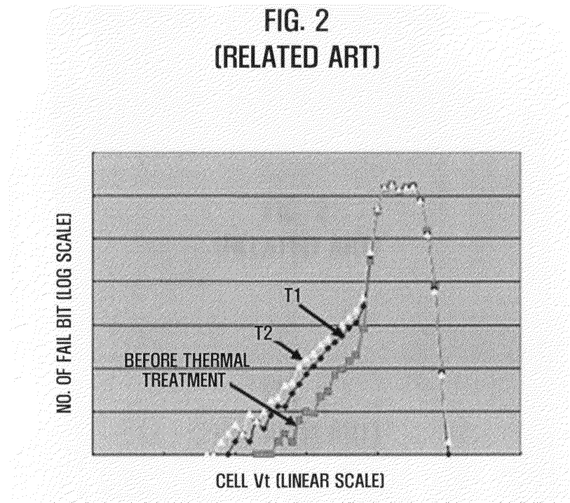

### DESCRIPTION OF EMBODIMENTS

Other objects and advantages of one or more embodiments can be understood by the following description, and become apparent with reference to the one or more embodiments.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

One or more embodiments are a method of fabricating a semiconductor device including a gate electrode having a so-called polymetal structure in which a polysilicon (poly-Si) layer and a metal layer are stacked. More particularly, one or more embodiments are a method of fabricating a semiconductor device that can perform a gate reoxidation process while suppressing or preventing oxidation of an interface where a metal layer contacts a polysilicon layer, without being affected by metal contamination.

To this end, one or more embodiments include a plasma-treated capping layer surrounding a gate pattern and formed there before the gate reoxidation process.

Hereinafter, the description will be made in connection with an example where one embodiment is applied to a cell transistor of a dynamic random access memory (DRAM) including a gate electrode having a polymetal structure.

### One Embodiment

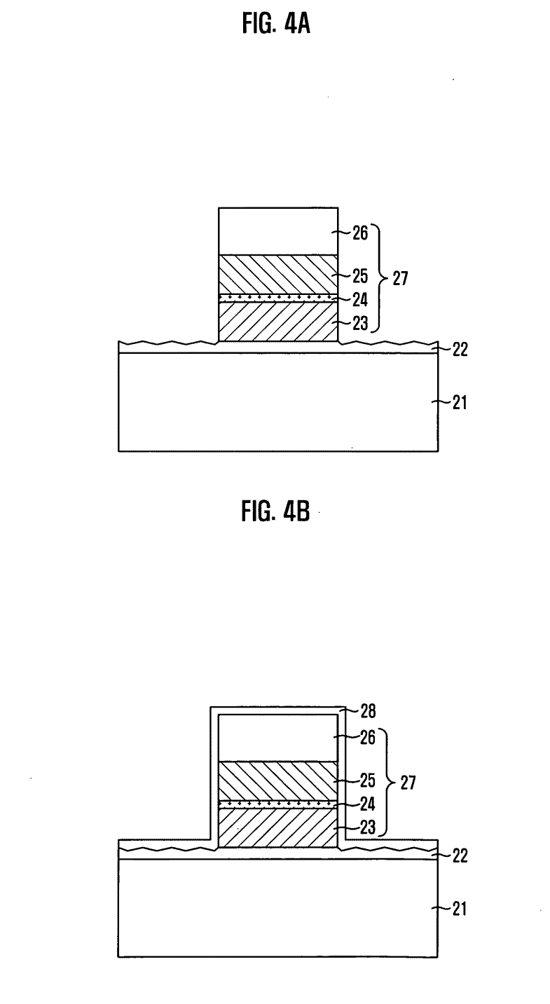

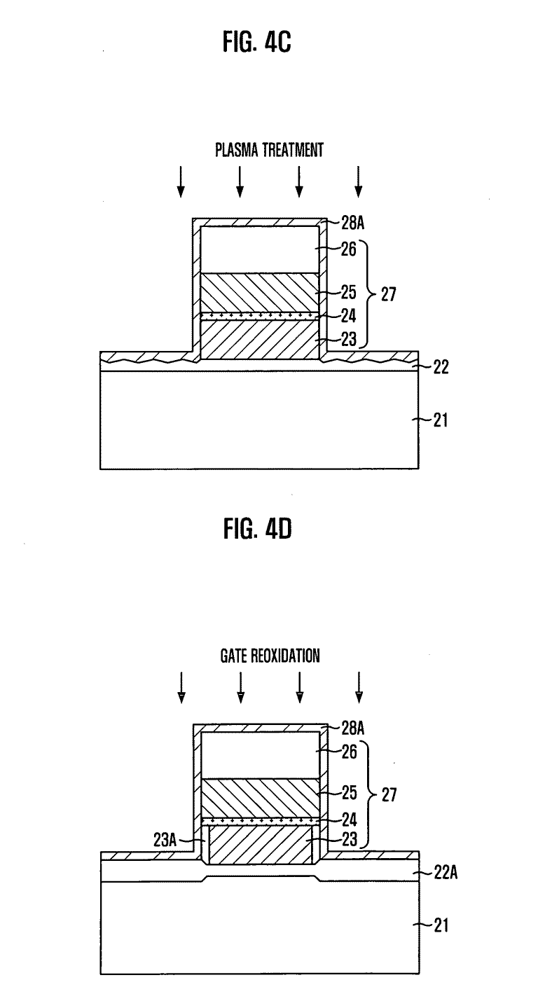

FIGS. 4A to 4D are cross-sectional views depicting stages in a method of fabricating a semiconductor device in accordance with the one embodiment.

Referring to FIG. 4A, a gate dielectric 22 is formed on a substrate 21. The gate dielectric 22 may be formed of oxide, for example, silicon oxide (SiO2) by a thermal oxidation process.

A nitridation treatment may be further performed in order to prevent impurities (e.g., boron (B)) contained in a silicon layer 23, which will be formed on the gate dielectric 22, from being penetrated into the substrate 21 in a subsequent process. The nitridation treatment may be performed by a furnace thermal treatment or a rapid thermal process in a nitrogen-containing gas atmosphere, for example, an N₂O or NO gas atmosphere.

A gate structure is formed on the gate dielectric 22. The gate structure may include a stacked structure in which a silicon layer 23, a diffusion barrier layer 24, a metal layer 25, and a gate hard mask layer 26 are sequentially stacked.

The silicon layer 23 may be formed of polysilicon (poly-Si). In addition, the silicon layer 23 may also be formed of silicon germanium (SiGe). In one or more embodiments, the silicon layer 23 may be a doped silicon layer where impurities such as boron (B) are doped.

The diffusion barrier layer 24 prevents inter-diffusion and mutual reaction on an interface where the silicon layer 23 contacts the metal layer 25 in a subsequent process. The diffusion barrier layer 24 may be formed of one of refractory metals selected from the group consisting of titanium (Ti), cobalt (Co), molybdenum (Mo), platinum (Pt), iridium (Ir), ruthenium (Ru), chromium (Cr), tantalum (Ta), and zirconium (Zr), or may be formed of a stacked layer of the refractory metals. Furthermore, a metal nitride such as tungsten nitride (WNₓ) where the refractory metal is combined with nitrogen (N) may be used as the diffusion barrier layer 24. Moreover, the diffusion barrier layer 24 may include a stacked structure where a refractory metal and a metal nitride are stacked. In accordance with the one embodiment, the diffusion barrier layer 24 is formed of tungsten nitride (WN).

The metal layer 25 may be formed of a material selected from the group consisting of tungsten (W), molybdenum (Mo), tantalum (Ta), titanium (Ti), ruthenium (Ru), iridium (Ir), and platinum (Pt). In accordance the one embodiment, the metal layer 25 is formed of tungsten.

The gate hard mask layer 26 protects a lower structure in a subsequent process and serves as an etch barrier in a patterning process. The gate hard mask layer 26 may include one or more selected from the group consisting of an oxide layer, a nitride layer, an oxynitride layer, or a stack structure of the foregoing layers. The oxide layer may include a silicon oxide (SiO₂) layer, a boron phosphorus silicate glass (BPSG) layer, a phosphorous silicate glass (PSG) layer, a tetra ethyle ortho silicate (TEOS) layer, an undoped silicate glass (USG) layer, a spin on glass (SOG) layer, a high density plasma (HDP) layer, or a spin on dielectric (SOD) layer. The nitride layer may include a silicon nitride (Si₃N₄) layer.

The oxynitride layer may include a silicon oxynitride (SION) layer.

A photoresist pattern (not shown) is formed on the gate hard mask layer 26. The gate structure is etched by using the photoresist pattern as an etch barrier to thereby form a gate pattern 27. Specifically, the gate hard mask layer 26 is etched by using the photoresist pattern as an etch barrier, and the metal layer 25, the diffusion barrier layer 24 and the silicon layer 23 are sequentially etched by using the etched gate hard mask layer as an etch barrier to thereby form the gate pattern 27.

The etching process for forming the gate pattern 27 may be performed by a dry etching process. The dry etching process may be performed by a plasma etching process. Accordingly, micro-trench and plasma damage occur in the surface of the gate dielectric 22 and the gate dielectric 22 under the lower edge of the gate pattern 27 which are exposed in the process of forming the gate pattern 27. This is depicted by the uneven lines on the upper surface of the gate dielectric 22 in FIG. 4A.

Although not shown, the etched surface of the silicon layer 23 may be formed to have a positive slope in order to maximally suppress the damage of the gate dielectric 22 under the lower edge of the gate pattern 27 in the etching process of forming the gate pattern 27. In one or more embodiments, the damage of the gate dielectric 22 will be recovered in a subsequent gate reoxidation process.

Referring to FIG. 4B, a capping layer 28 is formed over a resulting structure including the gate pattern 27. The capping layer 28 suppresses or prevents generation of metal contamination and oxidation of the interface where the silicon layer 23 contacts the metal layer 25 in a subsequent gate reoxidation process.

The capping layer 28 may be formed of an oxide such as silicon oxide. Such a silicon oxide layer included in the capping layer 28 may include SiOₓ (where x is a natural number), SiOₓF_{y} (where x and y are natural numbers), or SiOₓN_{y} (where x and y are natural numbers).

The capping layer 28 may be formed at a low temperature equal to or lower than 300° C. in order to prevent oxidation of the metal layer 25 in the process of forming the capping layer 28. Specifically, the capping layer 28 may be formed at a temperature of approximately 50° C. to approximately 250° C.

Examples of a method for forming the capping layer 28 in a low temperature (for example, a temperature equal to or lower than 300° C.) process may include an atomic layer deposition (ALD) process, a plasma enhanced atomic deposition (PEALD) process, a thermal oxidation process, and a chemical vapor deposition (CVD) process. However, the ALD process or the PEALD process may be preferable as a process of fabricating a semiconductor device, because the thermal oxidation process has problems in application because it requires much time at a low temperature. Likewise, the CVD process has problems in application because it is difficult to control uniformity of a thin layer.

On the other hand, because the ALD process or the PEALD process has a superior step coverage to that of the thermal oxidation process and the CVD process, the capping layer 28 can be formed over a resulting structure including the gate pattern 27 with a more uniform thickness.

The capping layer 28 may be formed to have a thin thickness, for example, approximately 50 Å to approximately 200 Å, considering a subsequent gate reoxidation process. If a thickness of the capping layer 28 is less than 50 Å, it is believed to be difficult to prevent metal contamination and oxidation of the interface where the silicon layer 23 contacts the metal layer 25 in a subsequent gate reoxidation process. On the other hand, if a thickness of the capping layer 28 is greater than 200 Å, the uneven upper surface of the gate dielectric 22 may not be smoothed in a subsequent gate reoxidation process.

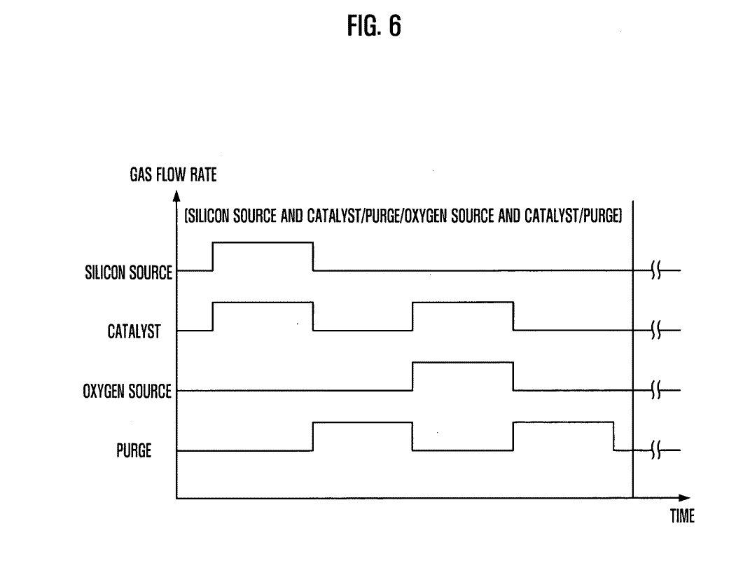

A method for forming the capping layer 28 of silicon oxide to a conformal thin thickness (for example, approximately 50 Å to approximately 200 Å) by using the ALD process at a low temperature (equal to or lower than 300° C.) will be described in detail below with reference to FIG. 6.

When the capping layer 28 is formed at a low temperature (equal to or lower than 300° C.) for preventing oxidation of the metal layer 25, it typically contains impurities such as chlorine (Cl) and carbon (C) therein. The impurities inside the capping layer 28 are generated by a silicon source gas and a catalyst for forming the capping layer 28 of silicon oxide at a low temperature (equal to or lower than 300° C.) (see FIG. 6). In this way, when the impurities exist in the capping layer 28, it is difficult to effectively prevent metal contamination and oxidation of the interface where the silicon layer 23 contacts the metal layer 25 in a subsequent gate reoxidation process. Moreover, the impurities inside the capping layer 28 may deteriorate the leakage current characteristics of the capping layer 28 and produce a plurality of trap charges in the capping layer 28.

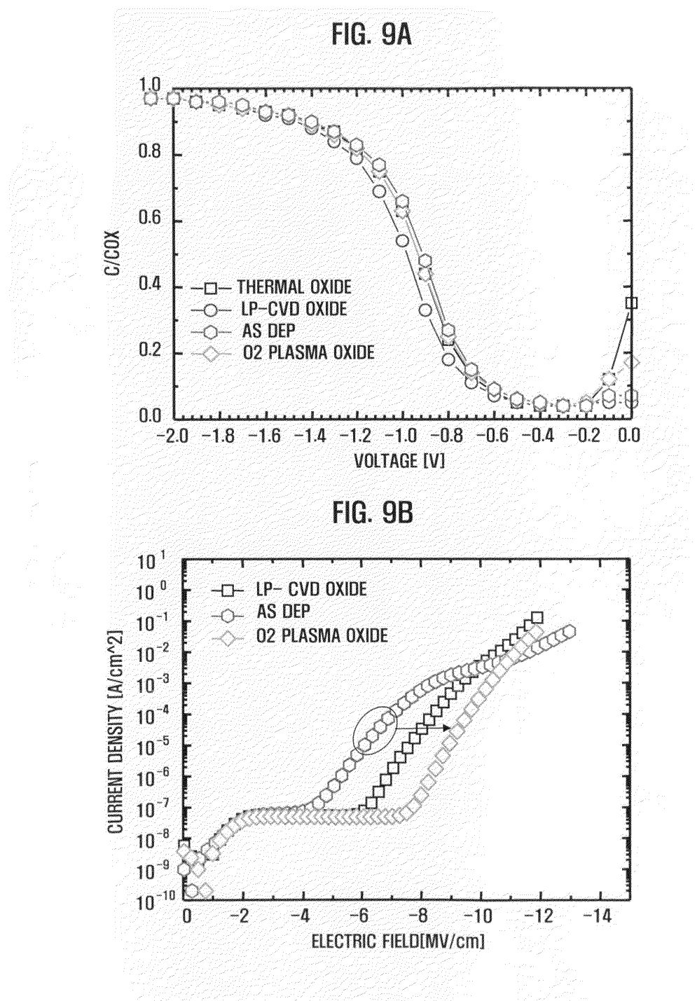

As illustrated in FIG. 4C, in order to prevent problems caused by the impurities inside the capping layer 28, plasma treatment is performed to remove impurities inside the capping layer 28 and densify the capping layer 28 (see FIGS. 9A and 9B). In one or more embodiments, the plasma treatment may be performed by using oxygen (O₂) plasma. Reference character 28A refers to the plasma-treated capping layer.

The following description pertains to removing the impurities (for example, chlorine and carbon) inside the capping layer 28A and simultaneously densifying the capping layer 28A through the plasma treatment.

In one or more embodiments, the substrate 21, the capping layer 28A, and the intervening layer(s) are loaded into a chamber, and plasma is formed inside the chamber by using an inert gas, for example, an argon gas (Ar). When an oxygen gas (O₂) is caused to flow into the chamber where the plasma is formed, an oxygen radical is produced while the oxygen gas is ionized due to the formed plasma. The oxygen radical produced by the plasma reacts with the impurities inside the capping layer 28A to produce a volatile byproduct, and the produced volatile byproduct can remove the impurities inside the capping layer 28A while being exhausted to outside the chamber. The produced volatile byproduct may be Clₓ O_{y} (where x and y are natural numbers) and CₓO_{y} (where x and y are natural numbers). Furthermore, the oxygen radical fills an empty space from which the impurities inside the capping layer 28A have been removed, thereby densifying the capping layer 28A. In one or more embodiments, the plasma treatment may be performed at a temperature of approximately 50° C. to approximately 250° C. for preventing oxidation of the metal layer 25 and simultaneously enhancing process efficiency.

In summary, the inert gas creates a plasma atmosphere inside the chamber, and the oxygen radical ionized from the oxygen gas by the plasma removes the impurities inside the capping layer 28A and densifies the capping layer 28A.

The impurities inside the capping layer 28A may be removed by using a typical thermal treatment, for example, a furnace thermal treatment or rapid thermal process (RTP) in an oxygen atmosphere. However, when the thermal treatment is performed at a low temperature (equal to or lower than 300° C.) by using the typical thermal treatment in order to prevent oxidation of the metal layer 25, a long time is taken in the process. This results in a corresponding decrease in productivity. Also, the impurities inside the capping layer 28A cannot be removed.

On the other hand, because the plasma treatment in accordance with the one embodiment uses high-activity radical produced by plasma, a process may be performed at a low temperature, for example, approximately 100° C. and oxidation of the metal layer 25 can be prevented in the plasma treatment. Furthermore, since the plasma treatment uses a high-activity radical even though it is performed at a low temperature, the associated processing time is less than that of a typical thermal treatment.

Referring to FIG. 4D, a gate reoxidation process is performed. The gate reoxidation process is performed for curing micro-trench and plasma damage occurring on the gate dielectric 22 in the process of forming the gate pattern 27.

The gate reoxidation process may be performed in one or more embodiments by using a selective reoxidation process in order to prevent oxidation of the metal layer 25. Reference character 22A refers to the gate dielectric 22 whose damage is cured through the gate reoxidation process.

The gate reoxidation process may be performed at a temperature higher than that of the plasma treatment by using a mixed gas of an oxygen-containing gas and a hydrogen-containing gas. In one or more embodiments, the oxygen-containing gas may include an H₂O gas or an O₂ gas, and the hydrogen-containing gas may include an H2 gas. For example, the gate reoxidation process may be performed by using an H₂O/H₂ mixed gas or an O₂/H₂ mixed gas at a temperature of approximately 700° C. to approximately 900° C.

Among the above-described mixed gases, the hydrogen-containing gas prevents oxidation of the metal layer 25 in the gate reoxidation process, and the oxygen-containing gas cures the damage of the gate dielectric 22.

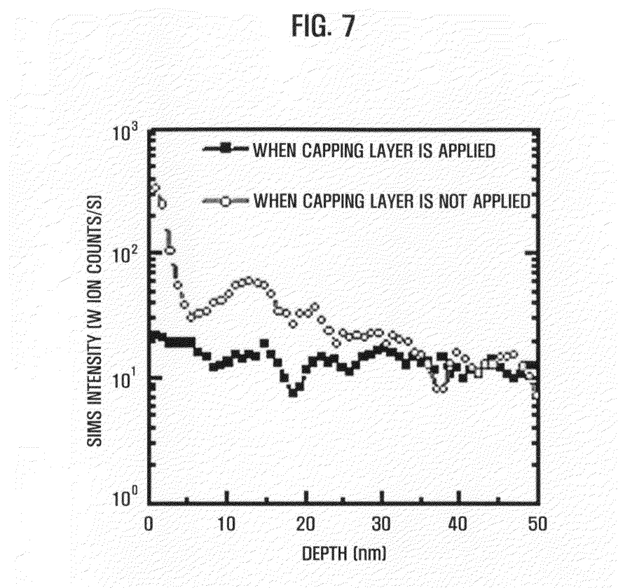

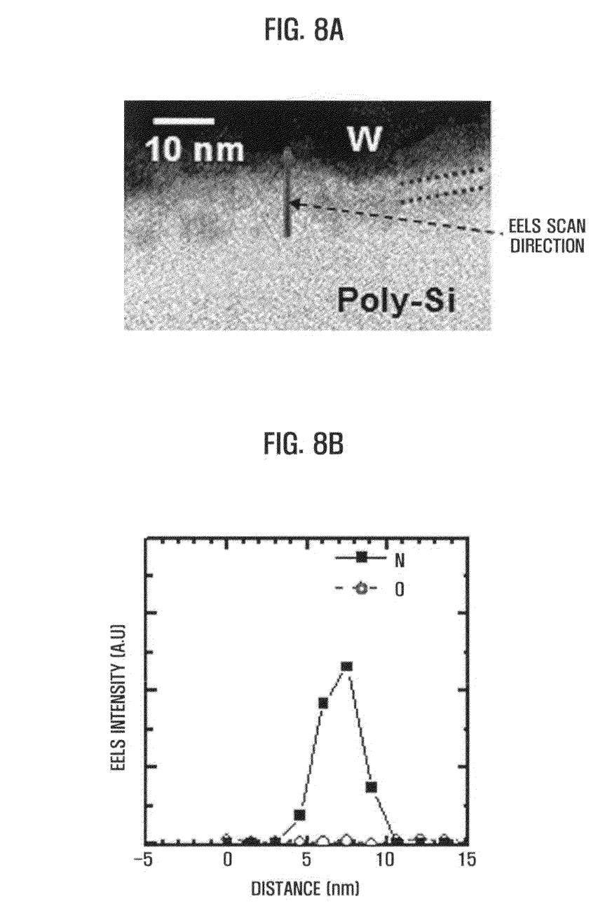

Through the gate reoxidation process, the oxide layer 23A is formed only on sidewalls of the silicon layer 23, and the damage of the gate dielectric 22A including the lower edge of the gate pattern 27 is cured. At this point, since the capping layer 28A surrounds the gate pattern 27, metal contamination and oxidation of the interface where the silicon layer 23 contacts the metal layer 25 can be prevented even though the gate reoxidation process is performed at a higher temperature, for example, approximately 700° C. to approximately 900° C., which is higher than in the plasma treatment (see FIGS. 7, 8A and 8B).

By performing the process of plasma-treating the capping layer 28A and the gate reoxidation process at the same time, it is possible to remove the impurities inside the capping layer 28A and obtain the gate dielectric 22A with the damage cured. This can be achieved by performing the gate reoxidation process in the plasma atmosphere. The following description pertains to simultaneously performing the plasma treatment and the gate reoxidation process according to the another embodiment.

Although not shown, the process of fabricating a semiconductor device is completed by performing a series of typical semiconductor device fabricating processes including, for example, an LDD ion injection process, a process of forming a spacer oxide layer of the gate pattern 27, and a source and drain ion injection process.

Even though a high temperature (equal to or higher than 300° C.) process is performed at an oxygen atmosphere like a process for completing the manufacture of a semiconductor device, in particular, the process of forming the spacer oxide layer of the gate pattern 27 after the gate reoxidation process, the capping layer 28A can prevent metal contamination and oxidation of the interface where the silicon layer 23 contacts the metal layer 25. Furthermore, the capping layer 28A can prevent oxidation of the metal layer 25.

Accordingly, in one or more embodiments, the formation of the capping layer 28A can prevent metal contamination and oxidation of the interface where the silicon layer 23 contacts the metal layer 25 in the gate reoxidation process and the subsequent process.

Furthermore, by performing the plasma treatment to remove the impurities inside the capping layer 28A and simultaneously densify the capping layer 28A, it is possible to further effectively prevent metal contamination and oxidation of the interface where the silicon layer 23 contacts the metal layer 25 in the gate reoxidation process and the subsequent process(es).

Moreover, by performing the process of forming the capping layer 28A at a low temperature (equal to or lower than 300° C.), it is possible to prevent oxidation of the metal layer 25 in the process of forming the capping layer 28A.

Accordingly, the method in accordance with one or more embodiments can enhance the electrical characteristics and yield of the semiconductor device including the gate electrode having the polymetal structure.

The following description pertaining to the another embodiment of the present invention is applied to a flash memory device.

### Another Embodiment

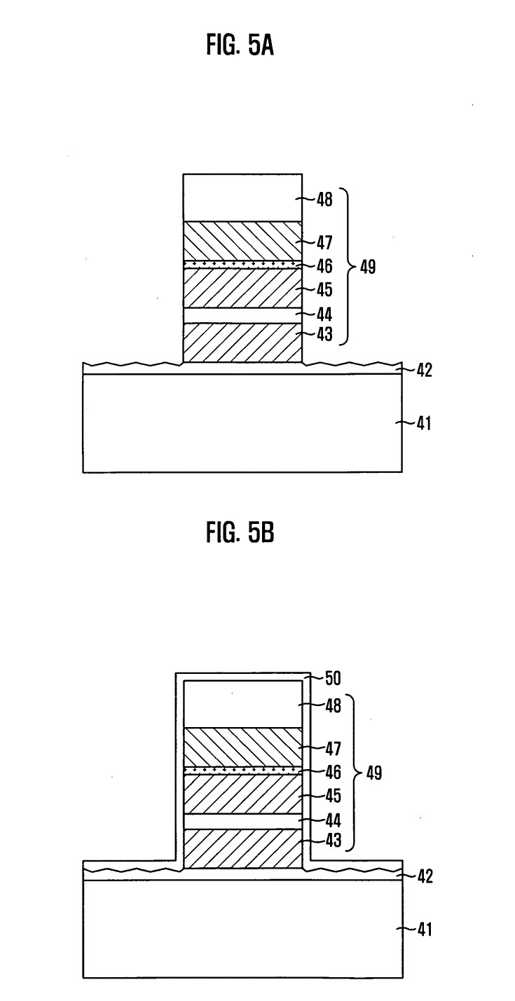

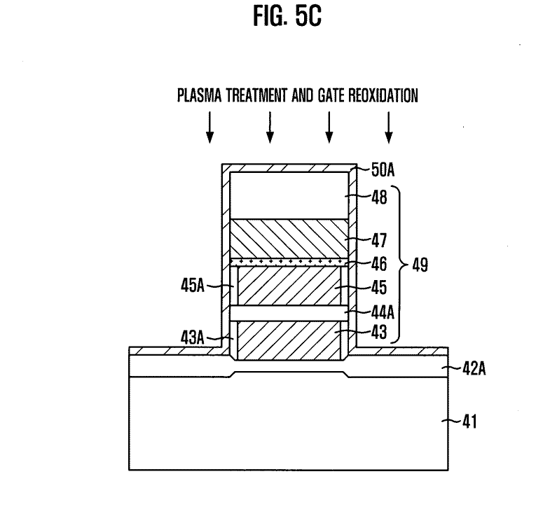

FIGS. 5A to 5C are cross-sectional views depicting stages in a method of fabricating a semiconductor device in accordance with the another embodiment.

Referring to FIG. 5A, a gate dielectric is formed on a substrate 41. The gate dielectric of the flash memory device is typically called a tunnel insulating layer 42. The tunnel insulating layer 42 may be formed of oxide, for example, silicon oxide (SiO₂) by thermal oxidation.

A nitridation treatment may be further performed in order to prevent impurities contained in a charge storage layer 43, which will be formed on the tunnel insulating layer 42, from being penetrated into the substrate 21 in a subsequent process. The nitridation treatment may be performed by using a furnace thermal treatment or a rapid thermal process in a nitrogen-containing atmosphere, for example, an N₂O or NO atmosphere.

A gate structure is formed on the tunnel insulating layer 42. The gate structure may have a stacked structure where a charge storage layer 43, a dielectric layer 44, a silicon layer 45, a diffusion barrier layer 46, a metal layer 47, and a gate hard mask layer 48 are sequentially stacked.

The charge storage layer 43 may include a silicon layer or an insulating layer. The silicon layer may include a polysilicon (poly-Si) layer or a silicon germanium (SiGe) layer. The insulating layer may include a silicon nitride (Si₃N₄) layer or an aluminum oxide (Al₂O₃) layer. Additionally, when the silicon layer is used as the charge storage layer 43, this is referred to as a charge storage type embodiment. When the insulating layer is used as the charge storage layer 43, this is referred to as a charge trap type embodiment.

The dielectric layer 44 may be formed as one or more selected from the group consisting of an oxide layer, a nitride layer, an oxynitride layer, or a stacked layer thereof. For example, the dielectric layer 44 may have a so-called ONO structure in which the oxide layer, the nitride layer, and the oxynitride layer are sequentially stacked.

The silicon layer 45 may be formed of polysilicon (poly-Si). Moreover, the silicon layer 45 may be formed of silicon germanium (SiGe), instead of polysilicon. At this point, the silicon layer 45 may be a doped silicon layer where impurities are doped.

The diffusion barrier layer 46 prevents inter-diffusion and mutual reaction on an interface where the silicon layer 45 contacts the metal layer 47 in a subsequent process. The diffusion barrier layer 46 may be formed of one of refractory metals selected from the group consisting of titanium (Ti), cobalt (Co), molybdenum (Mo), platinum (Pt), iridium (Ir), ruthenium (Ru), chromium (Cr), tantalum (Ta), and zirconium (Zr), or may be formed of a stacked layer of the refractory metals. Furthermore, a metal nitride such as tungsten nitride (WNₓ) where a refractory metal is combined with nitrogen (N) may be used as the diffusion barrier layer 46. Moreover, the diffusion barrier layer 46 may include a stacked structure where a refractory metal and a metal nitride are stacked. In accordance with the another embodiment, the diffusion barrier layer 46 is formed of tungsten nitride (WN).

The metal layer 47 may be formed of a material selected from the group consisting of tungsten (W), molybdenum (Mo), tantalum (Ta), titanium (Ti), ruthenium (Ru), iridium (Ir), and platinum (Pt). In accordance the another embodiment, the metal layer 47 is formed of tungsten.

The gate hard mask layer 48 protects a lower structure in a subsequent process and serves as an etch barrier in a patterning process. The gate hard mask layer 48 may be formed of one or more selected from the group consisting of an oxide layer, a nitride layer, an oxynitride layer, or a stacked layer thereof.

A photoresist pattern (not shown) is formed on the gate hard mask layer 48, and the gate structure is etched by using the photoresist pattern as an etch barrier to thereby form a gate pattern 49. Specifically, the gate hard mask layer 48 is etched by using the photoresist pattern as an etch barrier, and the metal layer 47, the diffusion barrier 46, the silicon layer 45, the dielectric layer 44, and the charge storage layer 43 are sequentially etched by using the etched gate hard mask layer 48 as an etch barrier to thereby form the gate pattern 49. For reference, in the gate pattern 49, the charge storage layer 43 is typically called a floating gate (FG), and the dielectric layer 44 is typically called a control dielectric. Also, the stacked layer of the silicon layer 45, the diffusion barrier layer 46 and the metal layer 47 is typically called a control gate (CG).

An etching process of forming the gate pattern 49 may be performed by a dry etching process. The dry etching process may be performed by a plasma etching process. Accordingly, micro-trench and plasma damage occur in sidewalls of the dielectric layer 44, the surface of the tunnel insulating layer 42 and the tunnel dielectric 42 under the lower edge of the gate pattern 49 which are exposed in the process of forming the gate pattern 49. This is depicted in FIG. 5A as an uneven upper surface of the tunnel insulating layer 42.

Although not shown, the etched surface of the charge storage layer 43 may be formed to have a positive slope in order to maximally suppress the damage of the tunnel insulating layer 42 at the lower edge of the gate pattern 49 in the etching process of forming the gate pattern 49. The uneven surface of the tunnel insulating layer 42 will be smoothed in a subsequent gate reoxidation process.

Referring to FIG. 5B, a capping layer 50 is formed over a resulting structure including the gate pattern 49. The capping layer 50 suppresses or prevents generation of metal contamination and oxidation of the interface where the silicon layer 45 contacts the metal layer 47 in a subsequent gate reoxidation process.

The capping layer 50 may be formed of oxide such as silicon oxide. The silicon oxide layer may include SiOₓ (where x is a natural number), SiOₓF_{y} (where x and y are natural numbers), or SiOₓN_{y} (where x and y are natural numbers).

The capping layer 50 may be formed at a low temperature equal to or lower than 300° C. in order to prevent oxidation of the metal layer 47 in the process of forming the capping layer 50. Specifically, the capping layer 50 may be formed at a temperature of approximately 50° C. to approximately 250° C.

Examples of a method of forming the capping layer 50 in a low temperature (for example, equal to or lower than 300° C.) process may include an atomic layer deposition (ALD) process, a plasma enhanced atomic deposition (PEALD) process, a thermal oxidation process, and a chemical vapor deposition (CVD) process. However, the ALD process or the PEALD process may be preferable for the process of fabricating a semiconductor device. This is true because the thermal oxidation process experiences problems in that it requires much time at a low temperature. Likewise, the CVD process experiences problems in that it is difficult to control uniformity of a thin layer.

On the other hand, because the ALD process or the PEALD process has a superior step coverage to that of the thermal oxidation process and the CVD process, the capping layer 50 can be formed over a resulting structure including the gate pattern 27 with a more uniform thickness.

The capping layer 50 may be formed to have a thin thickness, for example, approximately 50 Å to approximately 200 Å, considering a subsequent gate reoxidation process. If a thickness of the capping layer 50 is less than 50 Å, it is difficult to prevent metal contamination and oxidation of the interface where the silicon layer 45 contacts the metal layer 47 in a subsequent gate reoxidation process. On the other hand, if a thickness of the capping layer 50 is greater than 200 Å, the uneven upper surface of the gate dielectric 42 may not be smoothed in a subsequent gate reoxidation process.

A method for forming the capping layer 50 of silicon oxide to a uniformly thin thickness (for example, approximately 50 Å to approximately 200 Å) by using the ALD process at a low temperature (equal to or lower than 300° C.) will be described in detail below with reference to FIG. 6.

Since the capping layer 50 is formed at a low temperature (equal to or lower than 300° C.) for preventing oxidation of the metal layer 47, it contains impurities such as chlorine (Cl) and carbon (C) therein. The impurities inside the capping layer 50 are generated by a silicon source gas and a catalyst for forming the capping layer 50 of silicon oxide at a low temperature (equal to or lower than 300° C.) (see FIG. 6). In this way, when the impurities exist in the capping layer 50, it is difficult to effectively prevent metal contamination and oxidation of the interface where the silicon layer 45 contacts the metal layer 47 in a subsequent gate reoxidation process. Moreover, the impurities inside the capping layer 50 may deteriorate the leakage current characteristics of the capping layer 50 and produce a plurality of trap charges in the capping layer 50.

As illustrated in FIG. 5C, in order to prevent problems caused by the impurities inside the capping layer 50 and simplify the fabricating process, a gate reoxidation process is performed in a plasma atmosphere. That is, the plasma treatment for removing impurities inside the capping layer 50 and densifying the capping layer 50 and the gate reoxidation process for curing the damaged dielectric layer 44 and gate dielectric 42 are simultaneously performed (see FIGS. 9A and 9B). Reference character 50A refers to the plasma-treated capping layer, and reference characters 22A and 44A refer to the gate dielectric and the dielectric layer, respectively, whose damages are remedied by the gate reoxidation process.

Through the above-described processes, the impurities inside the capping layer 50A are removed and the layer is densified. Also, the oxide layers 43A and 45A are formed on sidewalls of the charge storage layer 43 and the silicon layer 45 formed of polysilicon, and the damages of the gate dielectric 42A and the dielectric layer 44A including the lower edge of the gate pattern 49 are cured. In one or more embodiments, since the capping layer surrounds the gate pattern 49, it is possible to prevent the generation of metal contamination and the oxidation of the interface where the silicon layer 45 contacts the metal layer 47 during the above-described processes (see FIGS. 7, 8A and 8B).

The following description pertains to removing the impurities (for example, chlorine and carbon) inside the capping layer 50A and simultaneously densifying the capping layer 50A through the gate reoxidation process at a plasma atmosphere.

The substrate 41 including the capping layer 50A is loaded into a chamber, and plasma is formed inside the chamber by using an inert gas, for example, an argon gas (Ar). A mixed gas of an oxygen-containing gas and a hydrogen-containing gas is caused to flow into the chamber where the plasma is formed. In one or more embodiments, H₂O gas or O₂ gas may be used as the oxygen-containing gas, and H₂ gas may be used as the hydrogen-containing gas. In accordance with the another embodiment, the gate reoxidation process may be performed at a temperature in a range from approximately 200° C. to approximately 900° C.

For example, if the H₂O/H₂ mixed gas or O₂/H₂ mixed gas is caused to flow into the chamber where the plasma is formed at a temperature range from approximately 200° C. to approximately 900° C., the H₂O/H₂ mixed gas or O₂/H₂ mixed gas is ionized by the plasma formed inside the chamber and thus a hydrogen (H) radial and an oxygen (O) radical are generated. The oxygen radical produced by the plasma reacts with the impurities (carbon and chlorine) inside the capping layer 50A to produce a volatile byproduct, and the produced volatile byproduct can remove the impurities inside the capping layer 50A while being exhausted to the outside of the chamber. Furthermore, the oxygen radical fills an empty space from which the impurities inside the capping layer 50A have been removed, thereby densifying the capping layer 50A. Furthermore, the oxygen radical reacts with the charge storage layer 43 and the silicon layer 45 formed of polysilicon to form oxide layers 43A and 45A on sidewalls thereof, and smoothes the uneven surfaces of the dielectric layer 44A and the gate dielectric 22A. At this point, the hydrogen radical serves to prevent the oxidation of the metal layer 47.

In summary, the inert gas creates the plasma atmosphere inside the chamber, and the oxygen radical generated from the oxygen gas by the plasma removes the impurities inside the capping layer 50A, densities the capping layer 50A, and smoothes the uneven surfaces of the gate dielectric 22A and the dielectric layer 44A. The hydrogen radical generated from the hydrogen gas by the plasma performs a selective oxidation to prevent the oxidation of the metal layer 47 between the processes.

Even though the gate reoxidation process is performed at a low temperature (lower than 300° C.), a processing time can be further reduced as compared to a typical thermal treatment because a high-activity oxygen radical is used. Furthermore, even though the gate reoxidation process is performed at a high temperature (higher than 300° C.), the hydrogen radical and the capping layer 50A can prevent the oxidation of the metal layer 47 and the oxidation of the interface between the silicon layer 45 and the metal layer 47.

As described in connection with the one embodiment, after performing the plasma treatment (oxygen plasma) at a low temperature (approximately 50° C. to approximately 250° C.) to remove the impurities inside the capping layer 50A and density the capping layer 50A, the gate reoxidation process may be performed by using a mixed gas of oxygen-containing gas and hydrogen-containing gas at a higher temperature (approximately 700° C. to approximately 900° C.) than the plasma treatment.

Although not shown, the process of fabricating a semiconductor device is completed by performing a series of typical semiconductor device fabricating processes including an LDD ion injection process, a process of forming a spacer oxide layer of the gate pattern 49, and a source and drain ion injection process.

Even though a high temperature (equal to or higher than 300° C.) process is performed at an oxygen atmosphere like a process for completing the manufacture of a semiconductor device, in particular, the process of forming the spacer oxide layer of the gate pattern 49 after the gate reoxidation process, the capping layer 50A can prevent metal contamination and oxidation of the interface where the silicon layer 45 contacts the metal layer 47. Furthermore, the capping layer 50A can prevent oxidation of the metal layer 47.

In this way, the formation of the capping layer 50A can prevent metal contamination and oxidation of the interface where the silicon layer 45 contacts the metal layer 47 in the gate reoxidation process and the subsequent process(es).

Furthermore, by performing the plasma treatment to remove the impurities inside the capping layer 50A and simultaneously densify the capping layer 50A, it is possible to further effectively prevent metal contamination and oxidation of the interface where the silicon layer 45 contacts the metal layer 47 in the gate reoxidation process and the subsequent process(es).

Moreover, the fabricating process can be simplified by performing the plasma treatment and the gate reoxidation process at the same time (that is, by performing the gate reoxidation process in the plasma atmosphere).

Moreover, by forming the capping layer 50A at a low temperature (equal to or lower than 300° C.), it is possible to prevent oxidation of the metal layer 47 between the processes.

Accordingly, one or more embodiments can enhance the electrical characteristics and yield of the semiconductor device including the gate electrode having the polymetal structure.

[Method for Forming Capping Layer]

FIG. 6 is a time graph of exemplary curves for parallel processes in a method of forming the capping layer described above in connection with the exemplary embodiments by using the ALD process.

Referring to FIG. 6, the capping layer described above in connection with the embodiments can be formed by performing the following exemplary unit cycle several times.

[Unit Cycle]

(silicon Source and Catalyst/Purge/Oxygen Source and Catalyst/Purge)

In the unit cycle, “silicon source” means injecting a silicon source gas for forming the silicon oxide layer, and “purge” means injecting a purge gas. “oxygen source” means injecting an oxygen source gas for forming the silicon oxide layer, and “catalyst” means injecting a catalyst gas for reducing a process temperature in the process of forming the silicon oxide layer. A total thickness of the capping layer can be controlled by repeatedly performing the unit cycle n times (where n is a natural number). That is, the capping layer having a thin thickness of, for example, approximately 50 Å to 200 Å can be formed by controlling the number of times the unit cycle is repeated.

More specifically, a silicon source is adsorbed by flowing the silicon source gas and the catalyst gas into the chamber which maintains a substrate temperature to 300° C. or lower (50° C. to 250° C.). In one or more embodiments, an argon gas (Ar) may be used as a carrier gas for the silicon source gas and the catalyst gas.

The silicon source gas may include one selected from the group consisting of SiCl₄, Si₂Cl₆ and Tris(DiMethylAmino)Silane (TDMA: (CH₃)₂N)₃SiH). The catalyst gas may include a gas containing an amine group (−NH₂). The gas containing the amine group may include an NH₃ gas or C₅H₅N gas.

A purge process is performed to flow an N₂ gas in order to remove the catalyst gas and the non-reacted silicon source gas.

An O₂ gas as the oxygen source gas and the catalyst gas are caused to flow to derive a reaction between the absorbed silicon source and O₃ gas to thereby deposit a silicon oxide layer at an atomic layer level. At this point, the O₃ gas acts as an oxidizing agent.

A purge process is performed to flow the N₂ gas in order to remove the catalyst gas, the non-reacted O₃ gas, and a reaction byproduct.

In addition to O₃ gas, an O₂ gas, an H₂O gas, an NO gas or an N₂O gas may be used as the oxygen source for oxidation of the silicon source. In addition to the N₂ gas, the inert gas such as an Ar gas may be used as the purge gas. As another purge process, a vacuum pump may be used to exhaust a residual gas or a reaction byproduct to the outside. In the process of forming the silicon oxide layer, a plasma atmosphere may be formed instead of using the catalyst gas in order to reduce the process temperature. The plasma atmosphere may be formed by using an argon gas (Ar) or a nitrogen gas (N₂). Both the catalyst gas and the plasma atmosphere may be used for reduce the process temperature.

The capping layer described in connection with the embodiments may be formed through the above-described processes.

By using the ALD process or the PEALD process, the capping layer can be formed to a uniform thickness over a resulting structure including the gate pattern at a low temperature (equal to or lower than 300° C.).

Moreover, by using the catalyst gas or the plasma atmosphere, the temperature for formation of the capping layer can be reduced. Accordingly, the oxidation of the metal layer can be effectively prevented in the process of forming the capping layer.

[Effects]

FIG. 7 is a graph of data points on curves illustrating a degree of metal-contamination according to the presence and absence of the capping layer. A tungsten (W) contamination degree was measured with a Secondary Ion Mass Spectroscopy (SIMS) in a region where an electrode having the polymetal structure is not formed.

It can be seen from FIG. 7 that the metal-contamination degree is much lower for embodiments where the capping layer is formed than for embodiments where the capping layer is not formed.

FIGS. 8A and 8B illustrate the polymetal interface of the semiconductor device including the gate electrode having the polymetal structure with the capping layer in accordance with one or more embodiments described above. Specifically, FIG. 8A is a picture of a cross section of the interface between the polysilicon (poly-Si) layer and the tungsten (W) layer, and FIG. 8B is a graph with data points and associated curves illustrating an exemplary analysis result of components between the polysilicon layer and the tungsten layer by using an Electron Energy Loss Spectroy (EELS). Although not shown clearly, a tungsten nitride (WNx) layer serving as a diffusion barrier layer is formed between the tungsten layer and the polysilicon layer.

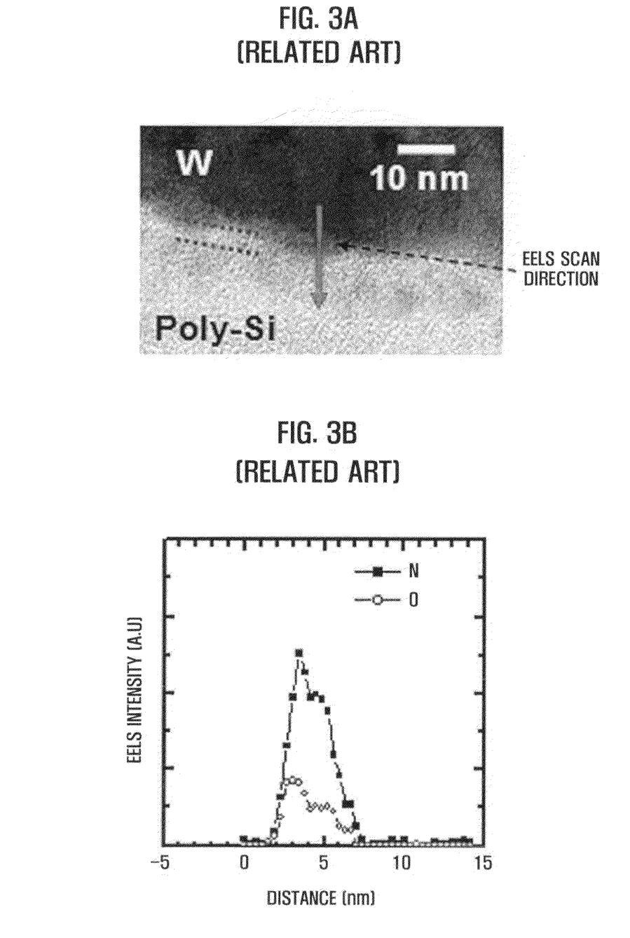

As described above with reference to FIGS. 3A and 3B, the typical gate electrode with the polymetal structure having no capping layer has a problem that a dielectric layer having a silicon oxide (SiOₓ) component is formed due to oxidation of the interface where the polysilicon layer contacts the tungsten layer after the gate reoxidation process.

However, as illustrated in FIGS. 8A and 8B showing the gate electrode with the polymetal structure having the capping layer in accordance with one or more embodiments, a dielectric layer having a silicon oxide component is not generated after the gate reoxidation process. Accordingly, one or more embodiments can prevent the increase of the vertical resistance in the gate electrode, thereby preventing signal delay in high-frequency operation.

Referring to EELS graphs of FIGS. 3B and 8B showing the analysis result of the components of the polymetal interface, a nitrogen (N) component is derived from the tungsten nitride (WNₓ) layer serving as the diffusion barrier layer formed between the polysilicon layer and the tungsten layer.

FIGS. 9A and 9B are graphs illustrating measurement results of the components of the capping layer in accordance with one or more embodiments. Specifically, FIG. 9A is a graph of curves containing the measurement results of a capacitance (C/Cox) with respect to a voltage (V), and FIG. 9B is a graph of curves containing the measurement results of a current density with respect to an electric field. An oxide layer (thermal oxide) formed by a thermal oxidation process, an oxide layer (LP-CVD oxide) formed by a low pressure chemical vapor deposition process, a capping layer (As Dep), and a oxygen-plasma-treated capping layer (O₂ plasma oxide) are compared with one another in the respective curves and the comparison result is graphed. This clearly shows some of the benefits of the capping layer in accordance with one or more embodiments.

It can be seen from FIG. 9A that the oxygen-plasma-treated capping layer (O₂ plasma oxide) in accordance with one or more embodiments has an electrical characteristic similar to that of the oxide layer (thermal oxide) formed by the thermal oxidation process, which has generally been known to have the most excellent characteristic.

It can be seen from FIG. 9B that the oxygen-plasma-treated capping layer (O₂ plasma oxide) in accordance with one or more embodiments has an even more excellent resistance to the electric field than the non-oxygen-plasma-treated capping layer (As Dep) and the oxide layer (LP-CVD oxide) formed by the low pressure chemical vapor deposition process.

Although, by way of example, the technical principles in accordance with the embodiments have been applied to the semiconductor device including the gate electrode having the polymetal structure, it should be apparent that the subject matter of the present disclosure can also be applied to any semiconductor device including the electrode having the polymetal structure.

By forming the capping layer, it is possible to prevent metal contamination and oxidation of the interface where the silicon layer contacts the metal layer in the gate reoxidation process and the subsequent process (especially, high-temperature (300° C. or higher) process in the oxygen atmosphere).

By removing the impurities in the capping layer and simultaneously densifying the capping layer, it is possible to further effectively prevent metal contamination and oxidation of the interface where the silicon layer contacts the metal layer in the gate reoxidation process and the subsequent process(es).

By performing the gate reoxidation process in the plasma atmosphere, it is possible to remove impurities in the capping layer, densifying the layer. In addition, the gate reoxidation process can be performed at the same time. Accordingly, the fabricating process of the semiconductor device can be simplified.

By forming the capping layer at a low temperature (equal to or lower than 300° C.), it is possible to prevent oxidation of the metal layer in the process of forming the capping layer.

Accordingly, it is possible to enhance the electrical characteristics and yield of the semiconductor device including the gate electrode having the polymetal structure.

While embodiments have been described, it will be apparent to those skilled in the art that various changes and modifications may be made.

What is claimed is:

1. A method of fabricating a semiconductor device, the method comprising:
forming a gate dielectric on a substrate;
forming a gate structure on the gate dielectric, the gate structure comprising a stacked layer of a silicon layer and a metal layer;
selectively etching the gate structure to form a gate pattern;
forming a capping layer surrounding the gate pattern;
plasma-treating the capping layer; and
performing a gate reoxidation process.

2. The method of claim 1, wherein plasma-treating the capping layer is performed by using oxygen (O₂) plasma.

3. The method of claim 1, wherein plasma-treating the capping layer comprises:
forming plasma in a chamber by using an inert gas; and
flowing oxygen gas (O₂) into the chamber where the plasma is formed.

4. The method of claim 1, wherein plasma-treating the capping layer is performed at a temperature lower than that of the gate reoxidation process.

5. The method of claim 4, wherein plasma-treating the capping layer is performed at a temperature of approximately 50° C. to approximately 250° C.

6. The method of claim 4, wherein the gate reoxidation process is performed at a temperature of approximately 700° C. to approximately 900° C.

7. The method of claim 1, wherein the gate reoxidation process is performed by using a mixed gas of an oxygen-containing gas and a hydrogen-containing gas.

8. The method of claim 7, wherein the oxygen-containing gas comprises an H₂O gas or an O₂ gas, and the hydrogen-containing gas comprises an H₂ gas.

9. The method of claim 1, wherein the capping layer is formed at a temperature of approximately 50° C. to approximately 250° C.

10. The method of claim 9, wherein the capping layer comprises a silicon oxide layer.

11. The method of claim 1, wherein the capping layer is formed by an atomic layer deposition (ALD) process or a plasma enhanced atomic layer deposition (PEALD) process.

12. The method of claim 1, wherein forming the capping layer comprises:
loading the substrate, on which the gate pattern is formed, into a chamber;
flowing a silicon source gas into the chamber;
purging the silicon source gas;
flowing an oxygen source gas into the chamber; and
purging the oxygen source gas.

13. The method of claim 12, wherein the silicon source gas comprises any one selected from the group consisting of Si₂Cl₆, SiCl₄ and Tris(DiMethylAmino)Silane (TDMS).

14. The method of claim 12, wherein the oxygen source gas comprises any one selected from the group consisting of O₂, O₃, NO, N₂O, and H₂O.

15. The method of claim 12, wherein the silicon source gas and the oxygen source gas are flowed by flowing gas containing an amine group into the chamber together with the silicon source gas and the oxygen source gas.

16. The method of claim 15, wherein the gas containing the amine group comprises an NH₃ gas or C₅H₅N gas.

17. The method of claim 12, wherein the capping layer is formed in a plasma atmosphere.

18. The method of claim 17, wherein the plasma atmosphere is formed by using an argon gas or a nitrogen gas.

19. The method of claim 1, wherein the metal layer comprises any one selected from the group consisting of tungsten (W), molybdenum (Mo), tantalum (Ta), titanium (Ti), ruthenium (Ru), iridium (Ir), and platinum (Pt).

20. The method of claim 1, wherein the gate structure comprises a stacked layer comprising a silicon layer, a metal layer, and a gate hard mask layer which are sequentially stacked, or a stacked layer comprising a charge storage layer, a dielectric layer, a silicon layer, a metal layer, and a gate hard mask layer which are sequentially stacked.

21. The method of claim 20, wherein the charge storage layer comprises a silicon layer or a dielectric layer.

22. A method of fabricating a semiconductor device, the method comprising:
forming a gate dielectric on a substrate;
forming a gate structure on the gate dielectric, the gate structure comprising a stacked layer of a silicon layer and a metal layer;
selectively etching the gate structure to form a gate pattern;
forming a capping layer surrounding the gate pattern;
plasma-treating the capping layer; and
performing a gate reoxidation process in a plasma atmosphere.

23. The method of claim 22, wherein performing the gate reoxidation process comprises:
forming plasma in a chamber by using an inert gas; and
flowing a mixed gas of an oxygen-containing gas and a hydrogen-containing gas into the chamber where the plasma is formed.

24. The method of claim 23, wherein the oxygen-containing gas comprises an H₂O gas or an O₂ gas, and the hydrogen-containing gas comprises an H₂ gas.

25. The method of claim 22, wherein the gate reoxidation process is performed at a temperature of approximately 200° C. to approximately 900° C.

26. A semiconductor device, comprising:
a gate dielectric formed on a substrate;
a gate pattern structure formed on the gate dielectric, the gate pattern structure comprising a stacked layer of a silicon layer and a metal layer; and
a capping layer surrounding the gate pattern structure.

27. The semiconductor device of claim 26, wherein the gate pattern structure comprises a stacked layer comprising a silicon layer, a metal layer, and a gate hard mask layer which are sequentially stacked, or a stacked layer comprising a charge storage layer, a dielectric layer, a silicon layer, a metal layer, and a gate hard mask layer which are sequentially stacked.

28. The semiconductor device of claim 27, wherein the charge storage layer comprises a silicon layer or a dielectric layer.
